(19) United States
(12) Patent Application Publication
(10) Pub. No.: US 2010/0296946 A1
(43) Pub. Date: Nov. 25, 2010

(54) PRESSURE SENSING DEVICE FOR ELECTRONIC DEVICE AND PRESSURE SENSING METHOD AND THERMAL DISSIPATION DEVICE THEREOF

(76) Inventors: Ming-Chih Chen, Taipei Hsien (TW); Jung-Chun Kuo, Taipei Hsien (TW); Chih-Hung Su, Taipei Hsien (TW); Yung-Li Jang, Taipei Hsien (TW); Ming-Che Lee, Taipei Hsien (TW); Ya-Lin Hsiao, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/769,658

(22) Filed: Apr. 29, 2010

(30) Foreign Application Priority Data
May 25, 2009 (TW) 098117268

(51) Int. Cl. F16K 37/00; G08B 21/00; H01L 23/467; F04B 49/06

(52) U.S. Cl. 417/44.2; 340/626; 137/557; 165/121

(57) ABSTRACT

A pressure sensing device for an electronic device includes a pressure sensing unit, a control unit, and an alarm unit. The pressure sensing unit is installed in the electronic device, and used for detecting fluid pressure to generate a pressure signal. The control unit is coupled to the pressure sensing unit, and used for determining variation in the fluid pressure in the electronic device according to the pressure signal and generating a control signal. The alarm unit is coupled to the control unit, and used for outputting an alarm signal according to the control signal to execute an alarm function.

### BACKGROUND OF THE INVENTION

1. Field of the Invention

The present invention relates to a pressure sensing device and a pressure sensing method and thermal dissipation device thereof, and more particularly, to a pressure sensing device capable of instantly sending an abnormal warning, and a pressure sensing method and thermal dissipation device thereof.

2. Description of the Prior Art

With the development of information technology, people are closely connected with computer systems. People frequently use computer systems whether they are at home or at work. As computer technology has evolved, a standard computer system, such as a laptop, a desktop or a server, not only has a faster operational clock in the central processing unit (CPU), but also has more powerful and versatile components. Therefore, an increasing amount of heat is generated during the operation of the modern computer system. If the heat is not able to dissipate, damage to the internal components may occur due to overheating. Thus, thermal dissipation efficiency of a computer system has a significant impact on the system's overall performance.

An ideal computer system has a perfectly-designed thermal dissipation device. However, buildup of dust or an inappropriate environment may cause the thermal dissipation device to malfunction, resulting in overheating. For example, different vents are set on the computer case for providing an airflow access. If the computer has been in use for a long duration, not only does dust buildup on the vent reduce the flux of the airflow, but also dust and particles accumulate on the internal components and the thermal dissipation device. In this situation, even if an anti-dust device is designed, it only can passively slow down the rate of the dust accumulation. Thus, in order to stabilize the operation of the computer system, the dust must first be cleared to dissipate the heat when a certain accumulation level is reached. In addition, when the computer is operated in an inappropriate environment, for example, the vent gets stuck because the laptop is put on the carpet, or the laptop is too close to a wall, the operation of the thermal dissipation device is affected, and thermal dissipation efficiency is reduced.

A user may operate the computer system in all kinds of environments. For example, when the user is operating the computer system at high altitude, the airflow generated from the thermal dissipation device's fan is relatively small because the density of the air is low. As a result, the reduction of the thermal dissipation efficiency affects the normal operation of the computer system. The current computer system design cannot be adjusted accordingly with the change of the operation environment, and so the system is not able to achieve the best performance.

### SUMMARY OF THE INVENTION

It is therefore an objective of the present invention to provide a pressure sensing device for an electronic device and a pressure sensing method and thermal dissipation device thereof.

An embodiment of the invention discloses a pressure sensing device for an electronic device. The pressure sensing device comprises a pressure sensing unit, a control unit, and an alarm unit. The pressure sensing unit is installed in the electronic device, and used for detecting fluid pressure to generate a pressure signal. The control unit is coupled to the pressure sensing unit, and used for determining variation in the fluid pressure in the electronic device according to the pressure signal and generating a control signal. The alarm unit is coupled to the control unit, and used for outputting an alarm signal according to the control signal to execute an alarm function.

An embodiment of the invention further discloses a pressure sensing method for an electronic device. The pressure sensing method comprises the steps of detecting fluid pressure to generate a pressure signal, determining variation in the fluid pressure in the electronic device according to the pressure signal and generating a control signal and outputting an alarm signal according to the control signal to execute an alarm function.

An embodiment of the invention further discloses a thermal dissipation device for an electronic device. The thermal dissipation device comprises a thermal dissipation module, a pressure sensing unit, and a control unit. The thermal dissipation module is installed in the electronic device and used for generating airflow via a fan to dissipate heat. The pressure sensing unit is used for detecting atmospheric pressure surrounding the electronic device to generate a pressure signal. The control unit is coupled to the pressure sensing unit and the thermal dissipation module, and used for determining variation in atmospheric pressure in the electronic device according to the pressure signal and generating a revolution control signal to control a rotational speed of the fan.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a pressure sensing device for an electronic device according to an embodiment of the invention.

FIG. 2 is a flowchart of a pressure sensing method according to an embodiment of the invention.

FIG. 3 is a schematic diagram of a thermal dissipation device of a laptop according to an embodiment of the invention.

FIG. 4 is a diagram of vents of a laptop according to an embodiment of the invention.

FIG. 5 is a schematic diagram of a thermal dissipation device for an electronic device according to an embodiment of the invention.

FIG. 6 is a flowchart of a pressure sensing procedure according to an embodiment of the invention.

### DETAILED DESCRIPTION

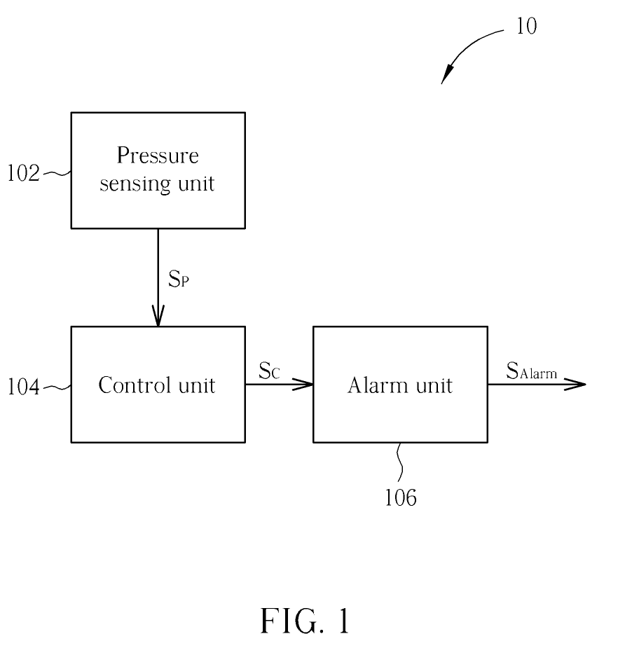

Please refer to FIG. 1, which is a schematic diagram of a pressure sensing device 10 for an electronic device according to an embodiment of the invention. The electronic device could be a laptop, a desktop or a server, and is not limited herein. The pressure sensing device 10 includes a pressure sensing unit 102, a control unit 104 and an alarm unit 106. The pressure sensing unit 102 is installed in the electronic device and used for detecting fluid pressure to generate a pressure signal S_{P}. The control unit 104 is coupled to the pressure sensing unit 102, and used for determining variations in the fluid pressure in the electronic device according to the pressure signal S_{P} and generating a control signal S_{C}. The alarm signal 106 is coupled to the control unit 104 and used for outputting an alarm signal S_{Alarm} according to the control signal S_{C} to execute an alarm function.

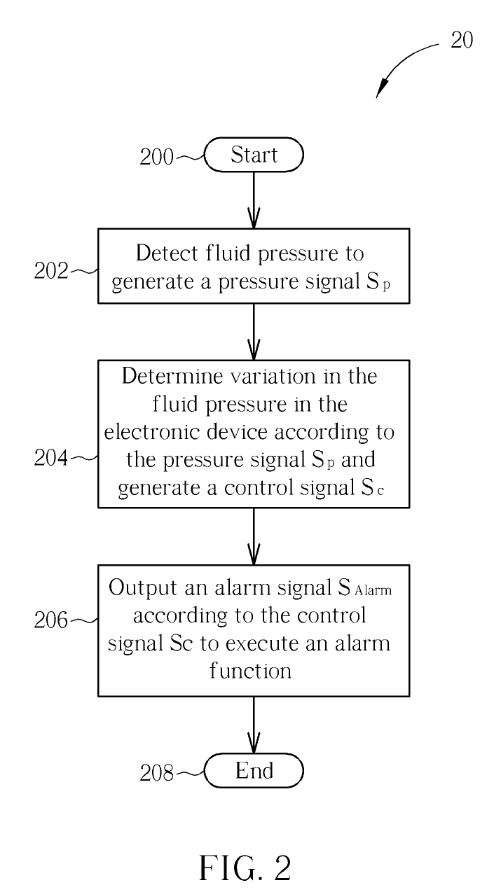

For an illustration of the operations of the pressure sensing device 10, please refer to FIG. 2. FIG. 2 is a flowchart of a pressure sensing process 20 according to an embodiment of the invention. The pressure sensing process includes the following steps:

Step 200: Start.

Step 202: Detect fluid pressure to generate a pressure signal S_{P}.

Step 204: Determine variation in the fluid pressure in the electronic device according to the pressure signal S_{P} and generate a control signal S_{C}.

Step 206: Output an alarm signal S_{Alarm} according to the control signal S_{C} to execute an alarm function.

Step 208: End.

According to the pressure sensing process 20, the pressure sensing device 10 detects the fluid pressure in the electronic device, such as pressure due to airflow, to determine an airflow condition inside the electronic device and further generates the alarm signal S_{Alarm} to inform the user of a dust buildup level or the operational environment. In other words, when the dust buildup of the electronic device or the current operation environment is severe enough that the thermal dissipation procedure does not function well, the pressure sensing device 10 can immediately detect the abnormal condition and inform the user to take corresponding actions.

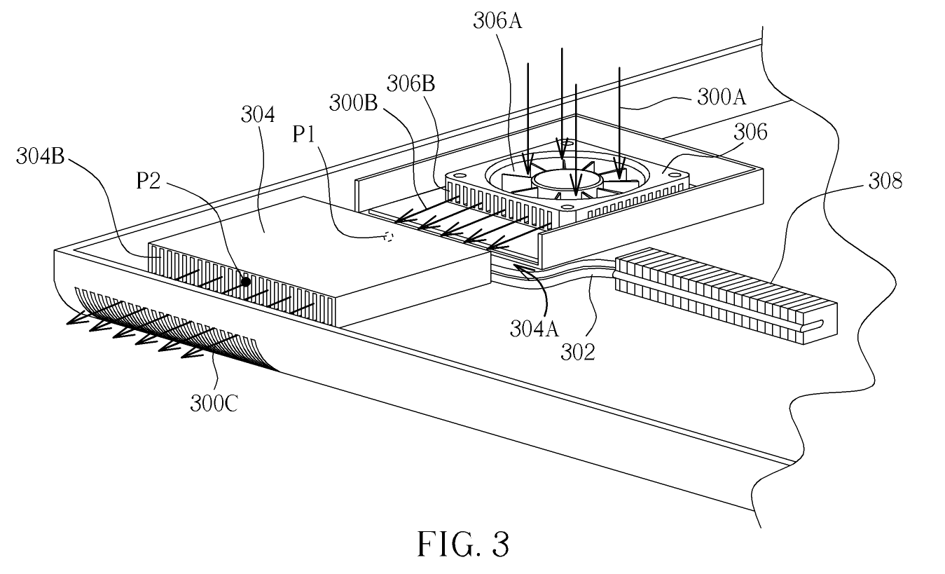

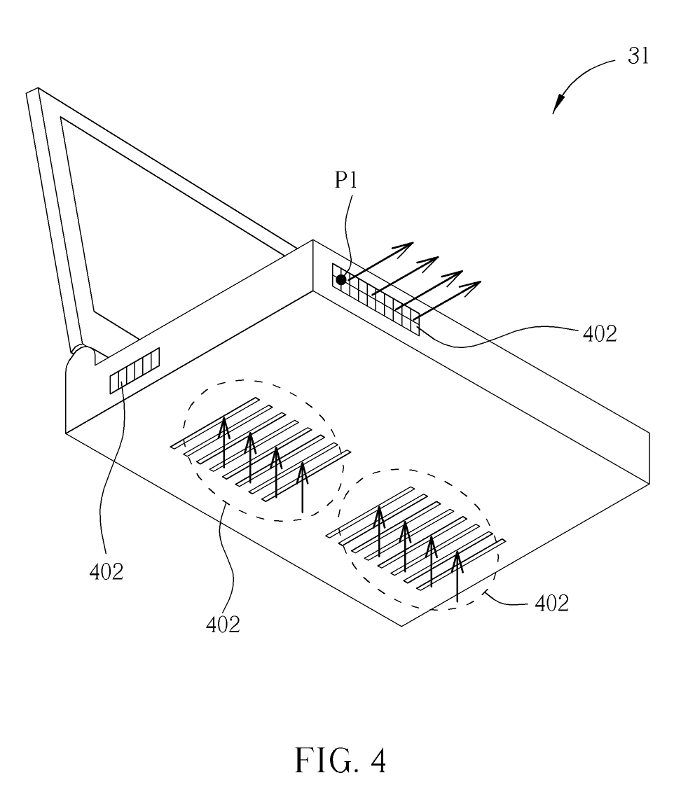

The embodiment of the invention takes corresponding actions by detecting the fluid pressure inside the electronic device and determining the airflow condition, and as a result will modify the normal operation of the electronic device. Please note that the electronic device is not restricted to a certain type. Any device that generates heat during operation is included within the scope of the invention. For example, please refer to FIG. 3 and FIG. 4. FIG. 3 is a schematic diagram of a thermal dissipation device 30 of a laptop 31 according to an embodiment of the invention. FIG. 4 is a diagram of a vent 402 of the laptop 31 according to an embodiment of the invention. Since the laptop 31 has limited room inside, all internal components, such as a CPU, chips or other electronic devices, are closely laid out. Once operation starts, the heat generated from all components is rapidly accumulated. Therefore, the dissipation device 30 is designed in the laptop 31 to extract heat generated from the internal components during operation out of the vent 40 shown in FIG. 4. In FIG. 3, the thermal dissipation device 30 includes a heat pipe 302, a heat sink 304 and a fan 306. The heat pipe 302 is connected to an internal component 308 of the laptop 31 and the heat sink 304 and transmits the heat generated by the internal component 308 during the operation to the heat sink 304, based on the heat pipe conducting the heat (from a high temperature to a low temperature). The fan 306 is installed on one side of the heat sink 304 and used for blowing the air towards the heat sink 304 for dissipating the heat on the heat sink 304. More specifically, the fan 306 of the thermal dissipation device 30 extracts the air from a fan air intake 306A along the direction of the arrow 300A, and blows the air towards an air exhaust 306B along the direction of the arrow 300B to form an air tunnel between each fin of the heat sink 304.

As shown in FIG. 3, the air blows from the air exhaust 306B into the air inlet 304A of the heat sink 304, and is extracted through an air outlet 304B along the direction of the arrow 300C. When the air is in the air tunnel of the heat sink 304 (flowing from the air inlet 304A to the air outlet 304B), the heat sink 304 absorbs the heat by heat switching. The warm air is extracted out of the air outlet 304B such that the heat generated by the internal component during operation can be dissipated. In this situation, the pressure sensing unit 102 can be located anywhere inside the laptop 31 to detect the pressure generated by the airflow.

For example, the pressure sensing unit 102 can be installed between the air exhaust 306B of the fan 306 and the heat sink 304 (e.g. position P1 as shown in FIG. 3) or on the air outlet 304B of the heat sink (e.g. position P2 as shown in FIG. 3), to detect the fluid pressure induced by the airflow. In addition, the pressure sensing unit 102 can be installed on the outside of the vent 402 (e.g. position P1 as shown in FIG. 4) or the inside of the vent 402 (not shown in FIG. 4) for detection. Since dust or particles gradually build up on the vent 402, the fan 306, the heat sink 304, and the internal component 308, the revolution of the vanes of the fan 306 slows down due to the dust buildup after a long accumulation. This may affect the thermal dissipation efficiency as the dust buildup on the vent 402 and the heat sink 304 could stop the air from flowing through. The airflow induced by the fan will be impacted correspondingly.

As a result, the mobility of the air inside the laptop 31 is reduced. Similarly, the pressure signal S_{P} detected by the pressure sensing unit 102 gets relatively small. Thus, taking an example of the position P1 shown in FIG. 3 where the pressure sensing unit is located, when the pressure sensing signal S_{P} is less than a first threshold value TH₁, the alarm unit 106 outputs the alarm signal S_{Alarm} according to the control signal S_{C} to inform the user to perform a dusting procedure. The first threshold value TH₁ could be a predetermined pressure value. The pressure signal S_{P} could also suddenly become weak due to the operational environment of the vent 402 (e.g. the vent 402 is blocked by carpet fibers). Also, the alarm unit 106 can be used to output the alarm signal S_{Alarm} for informing the user to perform an environment testing procedure, for example, checking the surroundings of the vent 402. Preferably, the alarm unit 106 outputs the alarm signal S_{Alarm} to a processing unit of the laptop 31 (e.g. CPU) to execute a pop-up window through an operation system, for informing the user to perform dusting or the environment testing procedure when the control signal indicates the pressure signal is less than the first threshold value TH₁.

Therefore, the embodiment of the invention combine the pressure sensing device 10 and the pressure sensing method to detect the dust buildup and abnormal conditions in real-time for informing the user. Consequently, the thermal dissipation efficiency of the laptop 31 is boosted, and further, the operation stability and lifetime of the laptop 31 is enhanced.

Please note that, in the laptop 31, the internal component 308 could be a CPU, a chip or other electronic device, and is not restricted herein. Furthermore, any device capable of detecting the fluid pressure can be used for implementing the pressure sensing unit 102. The pressure sensing unit 102 can be installed anywhere inside the laptop 31 for detection of the fluid pressure. There is no limitation to the number and appearance of the vents 402, as long as air can pass through. The alarm unit 106 could be an amplifier, a light emitting diode (LED) or a vibration unit, for informing the user through sound, light or vibration when the control signal indicates the pressure signal S_{P} is less than the first threshold value TH₁.

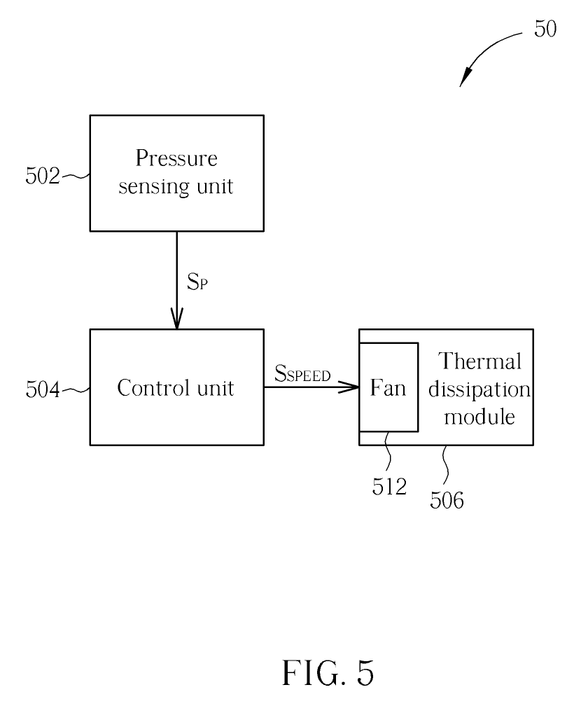

The user may operate the electronic device in all types of operational environments. The embodiment of the invention can adjust to a proper thermal dissipation function according to the different operational environments. Please refer to FIG. 5, which is a schematic diagram of a thermal dissipation device 50 for an electronic device according to an embodiment of the invention. The electronic device could be a laptop, a desktop, or a server, and is not restricted herein. The thermal dissipation device 50 includes a pressure sensing unit 502, a control unit 504, and a thermal dissipation module 506. The pressure sensing unit 502 is used for detection of atmospheric pressure surrounding the electronic device in order to generate a pressure signal S_{P}. The control unit 504 is coupled to the pressure sensing unit 502 and used for determining variation in the atmospheric pressure surrounding the electronic device and generating a revolution control signal S_{SPEED} to control the rotational speed of a fan 512 of the thermal dissipation module 506. Besides the fan 512, the thermal dissipation module 506 includes a heat pipe, a heat sink, and other common thermal dissipation components. Their location and function can be known by referring to FIG. 3 and are therefore not detailed here for brevity. In the pressure sensing unit 50, the control unit 504 generates the revolution control signal S_{SPEED} to accelerate the rotational speed of the fan 512 when the pressure signal S_{P} detected by the pressure sensing unit 502 is less than a second threshold value TH₂. Likewise, the control unit 504 generates the revolution control signal S_{SPEED} to decelerate the rotational speed of the fan 512 when the pressure signal S_{P} detected by the pressure sensing unit 502 is greater than a second threshold value TH₂. In addition, the pressure sensing unit 502 could be any device capable of detecting the atmospheric pressure, for example, an HCE pressure sensing device.

Therefore, the invention can detect the atmospheric pressure of the operation environment through the pressure sensing unit and make an appropriate adjustment by immediately performing the thermal dissipation procedure, thereby allowing the electronic device to achieve the best performance.

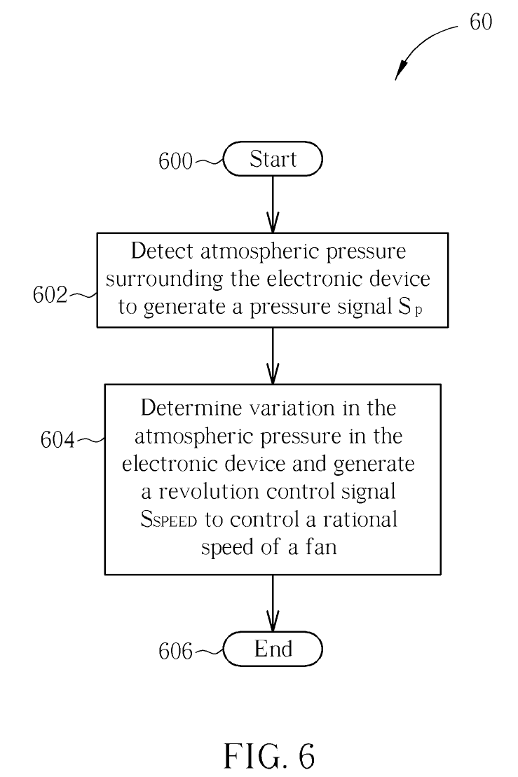

For an illustration of the operations of the pressure sensing device 50, please refer to FIG. 6. FIG. 6 is a flowchart of a pressure sensing procedure 60 according to an embodiment of the invention. The pressure sensing procedure 60 includes the following steps:

Step 600: Start.

Step 602: Detect atmospheric pressure surrounding the electronic device to generate a pressure signal S_{P}.

Step 604: Determine variation in the atmospheric pressure in the electronic device and generate a revolution control signal S_{SPEED} to control a rational speed of a fan 512.

Step 606: End.

The pressure sensing procedure 60 is used for describing the operations of the pressure sensing device. The detailed description and related derivatives can be found in the aforementioned description, and is therefore not elaborated on herein.

The invention estimates the air density by detecting the atmospheric pressure surrounding the electronic device and takes further actions to ensure the electronic device achieves the best efficiency. Please note that the electronic device is not limited to a certain type. Any electronic device or equipment that generates heat during operation is included within the scope of the invention. Taking the example of a laptop, the invention sends the pressure signal S_{P} to the control unit 504 to determine a state of the operation environment after detecting the atmospheric pressure surrounding the laptop through the pressure sensing unit 502. In this situation, the control unit 504 could be an embedded controller (EC) of the laptop or a keyboard controller (KBC). Thus, when the control unit 504 receives the pressure signal S_{P}, the pressure signal S_{P} is contrasted with a predetermined value in a lookup table. For example, when the pressure signal S_{P} is less than one atmosphere (1 atm), the control unit 504 will trigger a processing unit (e.g. CPU) to accelerate the rotational speed of the fan 512, and vice versa. Consequently, the laptop instantly adjusts to the best thermal dissipation efficiency according to the operational environment for stabilizing the laptop operation. By contrast, in the prior art, when the user is operating the computer system at a high altitude, the airflow generated by the fan of the thermal dissipation device is relatively small because the density of the air is low. This degrades the thermal dissipation efficiency and causes the computer system to malfunction.

To sum up, the invention combined with the pressure sensing method can instantly detect dust buildup and abnormal conditions to inform the user. Not only is the thermal dissipation efficiency boosted, but also the operation stability of the electronic device and lifetime of the internal components is enhanced. Moreover, the invention can detect atmospheric pressure through the pressure sensing unit and make a proper adjustment to perform an appropriate thermal dissipation procedure, thereby allowing the electronic device to achieve its best performance.

Those skilled in the art will readily observe that numerous modifications and alterations of the device and method may be made while retaining the teachings of the invention.

What is claimed is:

1. A pressure sensing device for an electronic device, the pressure sensing device comprising:
a pressure sensing unit installed in the electronic device for detecting fluid pressure to generate a pressure signal;
a control unit, coupled to the pressure sensing unit, for determining variation in the fluid pressure in the electronic device according to the pressure signal and generating a control signal; and
an alarm unit, coupled to the control unit, for outputting an alarm signal according to the control signal to execute an alarm function.

2. The pressure sensing device of claim 1, wherein the pressure sensing unit is installed on the outside of a vent.

3. The pressure sensing device of claim 1, wherein the pressure sensing unit is installed on the inside of a vent.

4. The pressure sensing device of claim 1, further comprising:
a heat pipe having one end connected to an internal component of the electronic device;
a plurality of heat sinks connected to the other end of the heat pipe, for dissipating heat transmitted from the heat pipe; and
a fan installed on one side of the plurality of heat sinks, for blowing air towards the plurality of heat sinks to dissipate heat on the plurality of heat sinks.

5. The pressure sensing device of claim 4, wherein the pressure sensing unit is installed between the fan and the plurality of heat sinks for detecting the fluid pressure generated from the fan.

6. The pressure sensing unit of claim 4, wherein the pressure sensing unit is installed between each of the plurality of heat sinks for detecting the fluid pressure generated from the fan.

7. The pressure sensing device of claim 1, wherein the alarm unit outputs the alarm signal to inform a user to perform a dusting procedure when the control signal indicates the pressure signal is less than a first threshold value.

8. The pressure sensing device of claim 1, wherein the alarm unit outputs the alarm signal to inform a user to perform a user environment testing procedure when the control signal indicates the pressure signal is less than a first threshold value.

9. The pressure sensing device of claim 1, wherein the electronic device is a computer system.

10. The pressure sensing device of claim 9, wherein the alarm unit outputs the alarm signal to a processing unit of the computer system to execute a pop-up window through an operation system of the computer system, for informing a user to perform a dusting procedure or a user environment testing procedure when the control signal indicates the pressure signal is less than a first threshold value.

11. The pressure sensing device of claim 1, wherein the alarm unit is an amplifier.

12. The pressure sensing device of claim 11, wherein the alarm unit is a sound generating unit.

13. The pressure sensing device of claim 1, wherein the alarm unit is a vibration unit.

14. A pressure sensing method for an electronic device, the pressure sensing method comprising the steps of:
detecting fluid pressure to generate a pressure signal;
determining variation in the fluid pressure in the electronic device according to the pressure signal and generating a control signal; and
outputting an alarm signal according to the control signal to execute an alarm function.

15. The pressure sensing method of claim 14, wherein the step of detecting the fluid pressure to generate the pressure signal comprises:
detecting pressure generated by airflow through a vent of the electronic device to generate the pressure signal.

16. The pressure sensing method of claim 14, wherein the step of detecting the fluid pressure to generate the pressure signal comprises:
detecting pressure generated by airflow induced by a fan to generate the pressure signal.

17. The pressure sensing method of claim 14, wherein the step of outputting the alarm signal according to the control signal to execute the alarm function comprises:
outputting the alarm signal to inform a user to perform a dusting procedure when the control signal indicates that the pressure signal is less than a first threshold value.

18. The pressure sensing method of claim 14, wherein the step of outputting the alarm signal according to the control signal to execute the alarm function comprises:
outputting the alarm signal to inform a user to perform a user environment testing procedure when the control signal indicates that the pressure signal is less than a first threshold value.

19. The pressure sensing method of claim 14, wherein the electronic device is a computer system.

20. The pressure sensing method of claim 19, wherein the step of outputting the alarm signal according to the control signal to execute the alarm function comprises:
outputting the alarm signal to a processing unit of the computer system to execute a pop-up window through an operation system of the computer system, for informing a user to perform a dusting procedure or a user environment testing procedure.

21. A thermal dissipation device for an electronic device, the thermal dissipation device comprising:
a thermal dissipation module installed in the electronic device, for generating airflow by a fan to dissipate heat;
a pressure sensing unit for detecting atmospheric pressure surrounding the electronic device to generate a pressure signal; and
a control unit, coupled to the pressure sensing unit and the thermal dissipation module, for determining variation in atmospheric pressure in the electronic device according to the pressure signal and generating a revolution control signal to control a rotational speed of the fan.

22. The thermal dissipation device of claim 21, wherein the thermal dissipation unit comprises:
a heat pipe having one end connected to an internal component of the electronic device; and
a plurality of heat sinks connected to the other end of the heat pipe, for dissipating heat transmitted from the heat pipe.

23. The thermal dissipation device of claim 22, wherein the fan is installed on one side of the plurality of heat sinks, for blowing air towards the plurality of heat sinks to dissipate heat on the plurality of heat sinks.

24. The thermal dissipation device of claim 21, wherein the pressure sensing unit is an HCE pressure sensing device.

25. The thermal dissipation device of claim 21, wherein the control unit generates the revolution control signal to accelerate the rotational speed of the fan when the pressure signal is less than a second threshold value.

26. The thermal dissipation device of claim 21, wherein the control unit generates the revolution control signal to decelerate the rotational speed of the fan when the pressure signal is greater than a second threshold.

27. A pressure sensing method for an electronic device, the pressure sensing method comprising the steps of:
detecting atmospheric pressure surrounding the electronic device to generate a pressure signal; and
determining variation in atmospheric pressure in the electronic device and generating a revolution control signal to control a rational speed of a fan.

28. The pressure sensing method of claim 27, wherein the step of determining variation in atmospheric pressure in the electronic device and generating the revolution control signal to control the rational speed of a fan comprises:
generating the revolution control signal to accelerate the rotational speed of the fan when the pressure signal is less than a second threshold value.

29. The pressure sensing method of claim 27, wherein the step of determining variation in atmospheric pressure in the electronic device and generating the revolution control signal to control the rational speed of a fan comprises:
generating the revolution control signal to decelerate the rotational speed of the fan when the pressure signal is greater than a second threshold value.
